(19) United States
(12) Patent Application Publication
(10) Pub. No.: US 2015/0197851 A1
(43) Pub. Date: Jul. 16, 2015

(54) PROCESS CHAMBER AND SUBSTRATE PROCESSING DEVICE

(71) Applicant: INOCT CO., LTD, Hwaseong-Si, Gyeonggi-Do (KR)

(72) Inventors: Song Keun Yoon, Yongin-Si (KR); Jong Hwa Lee, Suwon-Si (KR); Hyeog Joon Ko, Suwon-Si (KR); Jang Hyeok Lee, Suwon-Si (KR)

(21) Appl. No.: 14/411,478

(22) PCT Filed: Apr. 3, 2013
(86) PCT No.: PCT/KR2013/002747

§ 371 Date: Dec. 26, 2014

(30) Foreign Application Priority Data
Jun. 27, 2012 (KR) 10-2012-0069225

(51) Int. Cl. C23C 16/455; C23C 14/34; H01J 37/32; C23C 16/505; C23C 16/458

(52) U.S. Cl. CPC C23C 16/45504; C23C 16/505; C23C 16/45544; C23C 16/4584; C23C 16/45568; H01J 37/3211; H01J 37/32743; C23C 14/34

(57) ABSTRACT

The present invention relates to a process chamber and to a substrate processing device. The process chamber according to one embodiment of the present invention includes: a boat in which a plurality of substrates are vertically stacked apart from each; a chamber housing which raises the boat in order to position the boat in an inner space and horizontally injects a process gas from the sidewall and causes the process gas to flow between the substrates which are stacked apart from each other so as to discharge the process gas; a boat elevation unit which elevates the boat into the chamber housing; and a substrate transfer gate at which one side wall of the chamber housing is penetrated. Also, the substrate processing device according to one embodiment of the present invention includes: a process chamber having a boat which causes a plurality of substrates to be stacked apart from each other and injects process gas in between the substrates which are stacked apart from each other in the boat during rotation so as to discharge the process gas; a load lock chamber which is changed from a vacuum state to an atmospheric state or from an atmospheric state to a vacuum state; and a transfer chamber which transfers the substrate transferred in the load lock chamber to the process chamber and transfers the substrate transferred from the process chamber to the load lock chamber.

### TECHNICAL FIELD

The present invention relates to a process chamber and a substrate processing device, and more particularly, to a process chamber that is capable of improving substrate processing capability and a substrate processing device for processing a substrate by using the same.

### BACKGROUND ART

As semiconductor devices gradually decrease in scale, demand for ultra-thin films increases. In addition, as a contact hole is reduced in size, limitations in step coverage are increasing more and more.

In general, when semiconductor devices are manufactured in a semiconductor apparatus, a sputtering, chemical vapor deposition (CVD), or atomic layer deposition (ALD) method may be used for uniformly depositing a thin film.

Among these methods, the CVD method may be the most widely used deposition technology. In the CVD method, a thin film having a desired thickness may be deposited on a substrate by using a reaction gas and resolution gas. According to the CVD method, various gases may be injected into a process chamber, and then, the gases induced by high energy such as heat, light, or plasma may chemically react to deposit a thin film having a desired thickness on a substrate. Also, in the CVD method, reaction conditions may be controlled through a ratio and amount of plasma or gases applied to correspond to reaction energy to improve a deposition rate. However, since the reaction is quickly performed, it may be difficult to control thermodynamic stability of atoms, and also, the thin film may be deteriorated in physical, chemical, and electrically property.

The ALD method may be a method for alternately supplying a source gas (reaction gas) and purge gas to deposit an atomic layer. Here, a thin film formed by the ALD method may have good step coverage, be applicable for large diameter substrates and ultra-thin films, and has superior chemical and physical properties. In general, in the ALD method, a first source gas may be supplied to chemically adsorb one layer of first source on a surface of the substrate, and the physically adsorbed extra sources may be purged by allowing the purge gas to flow. Then, a second source gas may be supplied onto the one layer of source to allow the one layer of source to chemically react with the second source gas, thereby depositing a desired atomic layer thin film. Here, the extra reaction gas may form a thin film for one cycle in which the purge gas flows to purge the extra reaction gas. As described above, the ALD method may use a surface reaction mechanism to obtain the stable and uniform thin film. Also, in the ADL method, since the source gas and the reaction gas are separately successively injected and purged, generation of particles due to gas phase reaction may be restrained when compared to the CVD method.

FIG. 1 is a schematic view of a showerhead-type atomic layer thin film deposition device.

The showerhead-type atomic layer thin film deposition device includes a process chamber 2 having a reaction space in which a reaction gas and purge gas are successively supplied to deposit an atomic layer on a substrate 3, a substrate support 4 disposed in a lower portion of the process chamber 2 to seat the substrate 3 thereon, a showerhead 5 disposed to face the substrate support 4 to inject a gas into a reaction space 1, and a valve 6 disposed in a supply path that extends to the showerhead 5 to open or close the gas supply. Here, the process chamber 2 is connected to a pumping unit for discharging the gas supplied into the reaction space 1 to the outside. As described above, the atomic layer thin film deposition according to the related art includes the process chamber 2 having a relatively small volume to quickly supply and remove the gas in the reaction space 1 so as to expose the substrate to the reaction gas and purge gas at a uniform density.

In the case of the CVD or ALD method, substrate processing and production capabilities may not be superior. This is done for a reason in which it is difficult to process a large number of substrates at the same time because the number of substrates mounted on the substrate support is limited even though the CVD or ALD process is performed in a state where a plurality of substrates are placed on the substrate support.

(PRIOR ART DOCUMENT) Korean Patent Publication No. 10-2005-0080433

### DISCLOSURE OF THE INVENTION

### Technical Problem

The technical subject of the present invention is to provide a process chamber in which a substrate processing process such as a chemical vapor deposition (CVD) or atomic layer deposition (ALD) is performed and a substrate processing device. Also, the technical subject of the present invention is to provide a process chamber for improving substrate processing capability and a substrate processing device. Also, the technical subject of the present invention is to provide a process gas injection unit having a horizontal injection structure, but rather than a process gas injection unit having a vertical injection structure according to the related art.

### Technical Solution

A process chamber according to an embodiment of the present invention includes a boat in which a plurality of substrates are stacked to be spaced apart from each other, a chamber housing configured to lift the boat, thereby allowing the boat to be disposed in an inner space thereof, the chamber housing being configured to horizontally inject a process gas from a sidewall thereof, thereby allowing the process gas to flow between the substrates stacked to be apart from each other and discharge the process gas to the outside, a boat elevation unit configured to elevate the boat into the chamber housing, and a substrate transfer gate passing through one sidewall of the lower chamber housing.

Also, the chamber housing may include a lower chamber housing having a first inner space that is an inner space thereof, an upper chamber housing disposed above the lower chamber housing and having a second inner space that is an inner space thereof, the upper chamber housing being configured to horizontally inject the process gas from a sidewall thereof, thereby allowing the process gas to flow between the substrates stacked to be spaced apart from each other and discharge the process gas to the outside.

Also, the boat may include an upper plate, a lower plate, a plurality of support bars connecting the upper plate to the lower plate, and a plurality of substrate seat grooves defined in sidewalls of the support bars.

Also, the boat elevation unit may include a boat support configured to support the lower plate and an elevation rotation driving shaft passing through a bottom surface of the lower chamber housing to elevation the boat support upward and downward. Also, the elevation rotation driving shaft may be configured to rotate the boat support.

Also, the upper chamber housing may include an upper chamber inner housing in which the boat ascending through an opened lower side thereof is accommodated, an upper chamber outer housing surrounding a top surface and sidewall of the upper chamber inner housing in a state where the upper chamber outer housing is spaced apart from the upper chamber inner housing, a process gas injection unit configured to inject the process gas from one side inner wall of the upper chamber inner housing, and a process gas discharge unit configured to discharge the process gas that is used for processing the substrate in the inner space of the upper chamber inner housing to the outside.

Also, the process gas injection unit may include a process gas inflow space body having an inner space, a plurality of gas injection holes defined in a wall of the process gas inflow space body that is in contact with the boat, and a process gas supply tube configured to introduce the process gas into the inner space of the process gas inflow space body.

Also, the process gas discharge unit may include a process gas discharge space body having an inner space, a plurality of gas discharge holes defined in a wall of the process gas discharge space body that is in contact with the boat, a discharge pump configured to pump the process gas within the inner space of the process gas discharge space body to the outside, and a process gas discharge tube connecting the inner space of the process gas discharge space body to the discharge pump.

Also, the process gas inflow space body and the process gas discharge space body may be disposed on a wall of the upper chamber inner housing, and the process gas inflow space body and the process gas discharge space body may be disposed positions that face each other.

Also, the process chamber may further include a plasma generation unit configured to apply a plasma voltage to the upper chamber housing. The plasma generation unit may be disposed between the upper chamber inner housing and the upper chamber outer housing, and the plasma generation unit may be realized by using a U-shaped plasma antenna.

Also, the plasma antenna may have one end to which the voltage is applied and the other end that is a ground connection point, which are disposed above the upper chamber housing, and a connection line of the one end and the other end may cross in a U shape between the upper chamber inner housing and the upper chamber outer housing.

Also, a substrate processing device according to another embodiment of the present invention includes a process chamber including a boat in which a plurality of substrates are stacked to be apart from each other, the process chamber being configured to be rotated and to inject a process gas between the substrates stacked to be spaced apart from each other, thereby discharging the process gas to the outside, a load lock chamber that is changed from a vacuum state to an atmospheric state or from an atmospheric state to a vacuum state, and a transfer chamber configured to transfer the substrate transferred in the load lock chamber to the process chamber, the transfer chamber being configured to transfer the substrate transferred from the process chamber to the load lock chamber.

Also, the upper chamber housing of the substrate processing device includes an upper chamber inner housing in which the boat ascending through an opened lower side thereof is accommodated, an upper chamber outer housing surrounding a top surface and sidewall of the upper chamber inner housing in a state where the upper chamber outer housing is spaced apart from the upper chamber inner housing, a process gas injection unit configured to allow the process gas to flow from one side inner wall to the other side inner wall of the upper chamber inner housing, and a process gas discharge unit configured to discharge the process gas that reaches the other side inner wall of the upper chamber inner housing to the outside.

### Advantageous Effects

According to the embodiments of the present invention, the process gas may be horizontally injected from a side of the substrate while rotating the substrates vertically stacked and spaced apart from each other to improve the substrate processing capability. Also, various process processing methods may be performed and also be applied to, for example, the CVD and ALS devices. Also, the plasma generation unit may be provided to improve efficiency in substrate processing capability. Also, the deterioration in characteristic of the film quality in the existing showerhead method may be prevented to improve the film quality characteristics.

### BRIEF DESCRIPTION OF THE DRAWINGS

FIG. 1 is a schematic view of a showerhead-type atomic layer thin film deposition device.

FIG. 2 is a perspective view illustrating an exterior of a process chamber according to an embodiment of the present invention.

FIG. 3 is an exploded view of the process chamber according to an embodiment of the present invention.

FIG. 4 is a cross-sectional view of the process chamber in which a boat ascends or descends according to an embodiment of the present invention.

FIG. 5 is a view illustrating a state in which the boat ascends for each stage as a substrate is mounted on the boat according to an embodiment of the present invention.

FIG. 6 is a view illustrating a state in which a process gas inflow body, a process gas discharge space body, and a plasma generation unit are provided on an inner sidewall of an upper inner housing according to an embodiment of the present invention.

FIG. 7 is a view illustrating a flow of a process gas in an upper side of the process chamber according to an embodiment of the present invention.

FIG. 8 is a view illustrating a state in which a lower inner housing and the boat are coupled and sealed to each other according to an embodiment of the present invention.

FIG. 9 is a view illustrating a process in which the substrate is loaded on the boat and is processed within a chamber housing, and then, is unloaded again from the boat according to an embodiment of the present invention.

FIG. 10 is a conceptual view of a substrate processing device according to an embodiment of the present invention.

### MODE FOR CARRYING OUT THE INVENTION

Hereinafter, specific embodiments will be described in detail with reference to the accompanying drawings. The present invention may, however, be embodied in different forms and should not be construed as limited to the embodiments set forth herein. Rather, these embodiments are provided so that the present invention will be thorough and complete, and will fully convey the scope of the present invention to those skilled in the art. In the figures, like reference numerals refer to like elements throughout.

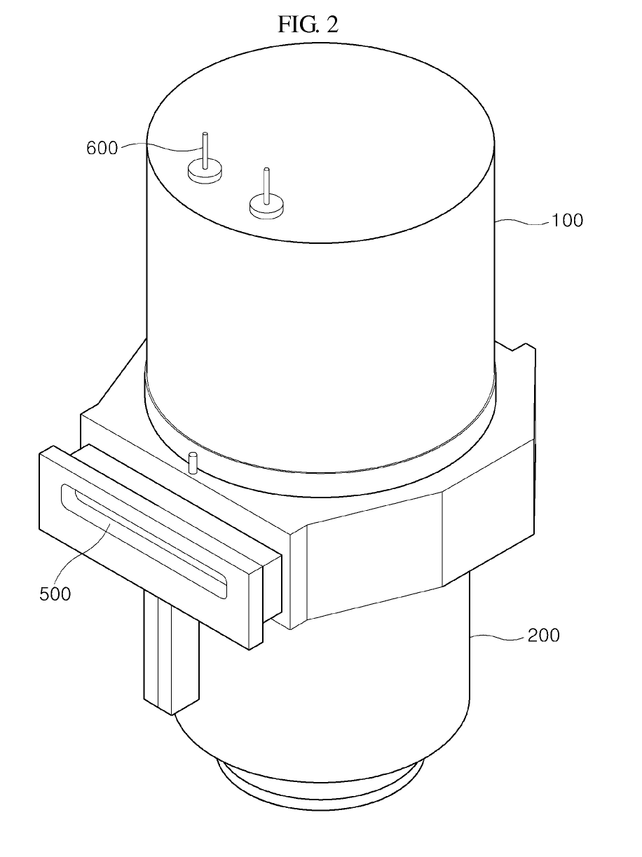

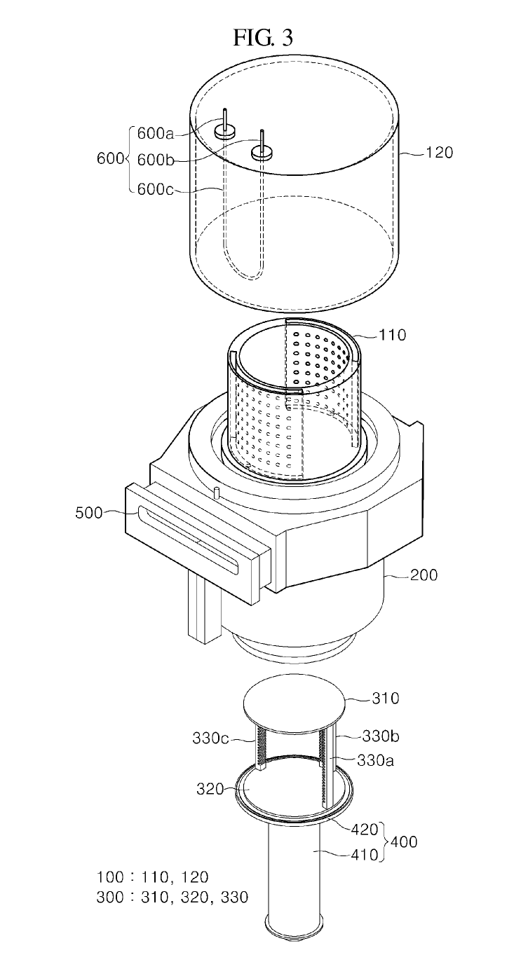

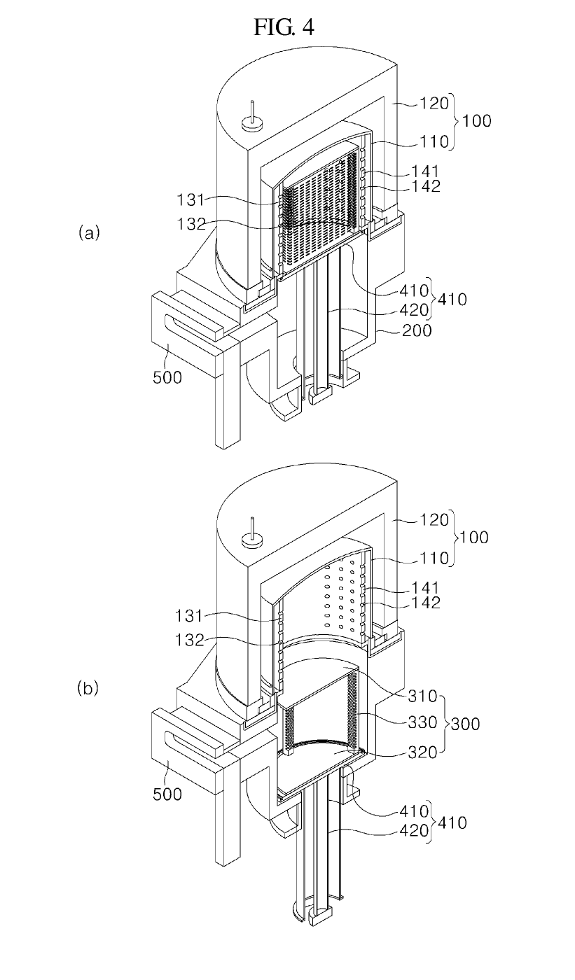

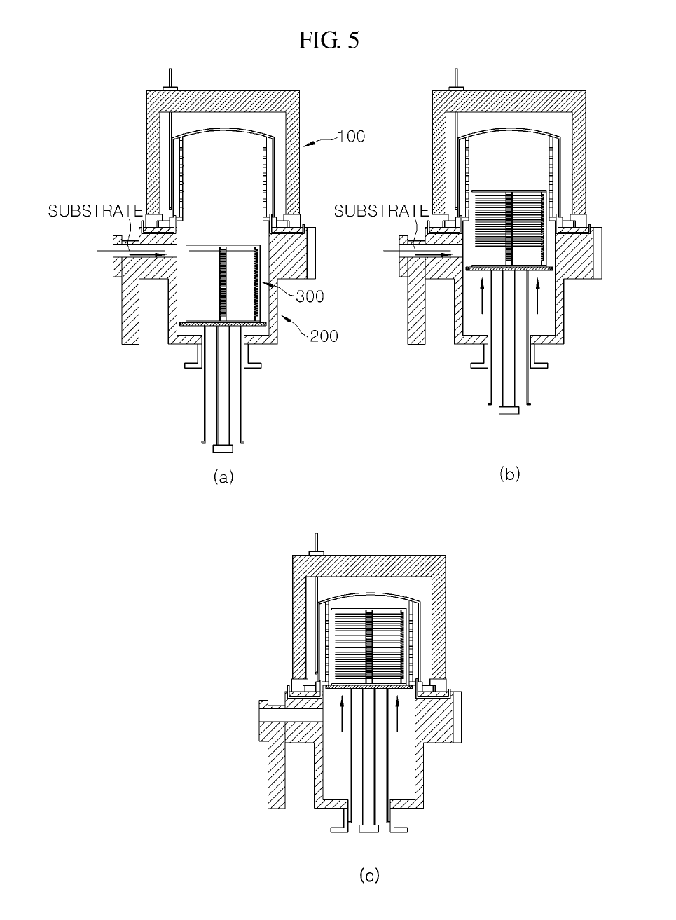

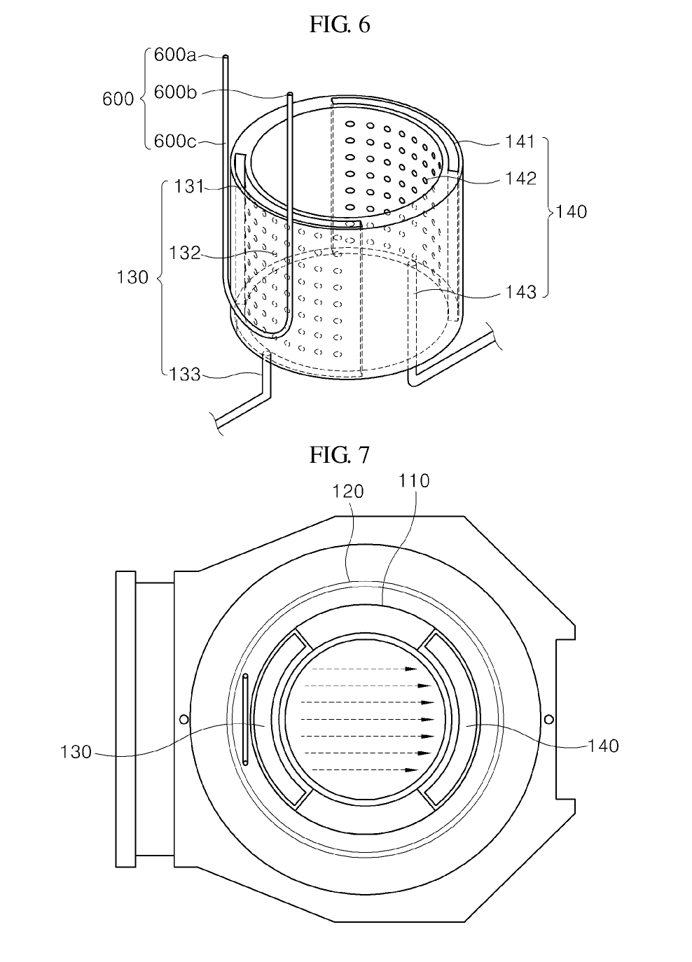

FIG. 2 is a perspective view illustrating an exterior of a process chamber according to an embodiment of the present invention, FIG. 3 is an exploded view of the process chamber according to an embodiment of the present invention, FIG. 4 is a cross-sectional view of the process chamber in which a boat ascends or descends according to an embodiment of the present invention, FIG. 5 is a view illustrating a state in which the boat ascends for each stage as a substrate is mounted on the boat according to an embodiment of the present invention, and FIG. 6 is a view illustrating a state in which a process gas inflow body, a process gas discharge space body, and a plasma generation unit are provided on an inner sidewall of an upper inner housing according to an embodiment of the present invention.

A process chamber provides a space in which a plurality of substrates are vertically stacked to be spaced apart from each other to allow a process gas to flow between the plurality of substrates, thereby performing substrate processing processes such as a deposition process, an etching process, and the like on the substrates so as to improve substrate processing capability. For this, the process chamber includes a boat 300 in which a plurality of substrates are stacked to be spaced apart from each other, chamber housings 100 and 200 disposed on a sidewall thereof to horizontally inject a process gas and flow between the spaced and stacked substrates, thereby discharging the process gas to the outside, a boat elevation unit 400 for elevating the boat within the chamber housings 100 and 200, and a substrate transfer gate 500 passing through one sidewall of the chamber housings 100 and 200.

Since the plurality of substrates are vertically stacked to be spaced apart from each other on the boat 300, a gap may be formed between the stacked substrates to allow the process gas to be introduced therethrough and then to flow in an opposite side. Thus, the process gas may contact a top surface of each of the substrates to perform a processing process such as a deposition or etching process on the substrates. To stacking the substrates in the state where the substrates are spaced apart from each other, the boat 300 includes an upper plate 310, a lower plate 320, a plurality of support bars 330 (330a, 330b, and 330c) connecting the upper plate 310 to the lower plate 320, and a plurality of substrate seat grooves 331 defined in sidewalls of the support bars 330. Each of the substrate seat grooves 331 may be a groove that is recessed from the sidewall of each of the support bars 330. Here, the substrate may be seated into the groove.

The substrate transfer gate 500 may be a gate that is disposed on one sidewall of the lower chamber housing 200 to allow the substrate to be accessible to the boat 300. When the substrate is loaded on or unloaded from the boat 300, the substrate may be transferred through the substrate transfer gate.

The boat elevation unit 400 may elevate the boat 300 between an inner space of the upper chamber housing 100 and an inner space of the lower chamber housing 200. For this, the boat elevation unit 400 includes a boat support 420 and an elevation rotation driving shaft 410. The boat support 420 has a top surface supporting the lower plate 320. The elevation rotation driving shaft 410 may pass through a bottom surface of the lower chamber housing 200 to support a bottom surface of the boat 300, i.e., the lower plate 320 of the boat 300. The bottom surface of the boat support 420 is connected to the elevation rotation driving shaft 410 to ascend or descend according to the driving of the vertically reciprocating driving source such as a motor. Here, boat 300 may ascend or descend through a vertical piston reciprocating motion of the boat support 420. Also, the elevation rotation driving shaft 410 may not elevate the boat at once when the boat is elevated (ascends/descends), but may allow the boat to ascend or descend for each stage. For example, when the substrate is inserted and seated into the substrate seat groove of the boat through the substrate transfer gate as illustrated in FIG. 5A, the boat elevation unit may further left the boat by one stage to allow the next substrate seat groove to reach the substrate transfer gate as illustrated in FIG. 5B. As described above, the boat may ascend for each stage to seat the substrate into each of the substrate seat grooves. Then, as illustrated in FIG. 5C, the substrate may be mounted into the substrate seat groove and inserted into the inner space of the upper chamber housing. Also, the elevation rotation driving shaft may rotate the boat support to rotate the boat connected to the boat support. Thus, when the processes are performed regardless of a chemical vapor deposition (CVD) process and an atomic layer deposition (ALD) process, the boat may be rotated to allow the substrate mounted on the boat to be repeatedly successively exposed to a source gas, a purge gas, and a reaction gas.

The chamber housings 100 and 200 may lift the boat to allow the boat to be disposed in the inner space thereof and may horizontally inject the process through one side inner wall thereof to allow the process gas to flow between the spaced and stacked substrates, thereby discharging the process gas to the outside. The chamber housing according to an embodiment of the present invention may be constituted by the lower chamber housing 200 and the upper chamber housing 100.

The lower chamber housing 200 may have an opened upper side and an inner space (hereinafter, referred to as a “first inner space”). As illustrated in FIG. 4B, in a state where the process is completed to allow the substrate to be unloaded, the descending boat 300 may be disposed in the first inner space of the lower chamber housing 200. On the other hand, when the substrate is loaded into the substrate seat groove of the boat by each stage to ascend, the boat 300 may not exist in the first inner space of the upper chamber housing 100.

The upper chamber housing 100 may be disposed on the lower chamber housing 200 in a state where a lower side of the upper chamber housing 100 is opened to define an inner space (hereinafter, referred to as a “second inner space”). The boat ascending from the first inner space of the lower chamber housing is disposed in the second inner space of the upper chamber housing 100. Here, the substrates may be in a state in which the substrates are stacked to be spaced apart from each other and mounted into the substrate seat groove of the boat. The process gas is injected from one side inner wall of the upper chamber housing 100 to flow between the spaced and stacked substrates on the boat. Then, the process gas may pass through the other inner sidewall of the upper chamber housing and be discharged to the outside.

When the process gas is injected from the one side inner wall to the other side inner wall of the upper chamber housing 100, the upper chamber housing 100 may be provided as a single wall. Alternatively, the upper chamber housing 100 may be provided as a double wall. That is, the upper chamber housing 100 may be provided as a housing having a double structure including an upper chamber inner housing 110 and an upper chamber outer housing 120 surrounding the upper chamber inner housing 110. The boat 300 ascending from the lower chamber housing 200 is accommodated into the upper chamber inner housing 110 that is disposed at a relatively inner side of the double structure, and the upper chamber outer housing 120 that is disposed at a relatively outer side of the double structure may surround the top surface and sidewall of the upper chamber inner housing 110 in a state where the upper chamber outer housing 120 is spaced apart from the top surface and sidewall of the upper chamber inner housing 110.

A process gas injection unit for injecting the process gas toward the other side inner wall that is opposite to the one side inner wall of the upper chamber inner housing 110 and a process gas discharge unit for discharging the process gas within the housing to the outside are disposed on the one side inner wall of the upper chamber inner housing 110. As the process gas is injected toward the other side inner wall opposite to the one side inner wall, the process gas may flow onto the boat existing in the inner space of the upper chamber housing.

As illustrated in FIG. 6, the process gas injection unit 130 includes a process gas inflow space body 131 having an inner space, a plurality of gas injection holes 132 defined in a wall of the process gas inflow space body that is adjacent to the boat, and a process gas supply tube 133 for introducing the process gas into the inner space of the process gas inflow space body 131. The process gas inflow space body 131 may be a space body having an inner space defined by upper/lower and left/right walls. The gas introduced from the process gas supply tube 133 may exist in the inner space. A plurality of gas injection holes 132 passing toward the inner space of the process gas inflow space body 131 are defined in a wall of the process gas inflow space body. The process gas may be introduced into the inner space of the upper chamber inner housing through the gas injection holes 132. The gas injection holes 132 may be provided in plurality in positions that respectively match the gaps between the mounted substrates. The wall of the process gas inflow space wall may be a wall facing the boat. The process gas supply tube 133 may introduce the process gas into the inner space of the process gas inflow space body 131. That is, the process gas stored in a process gas storage tank may be supplied into the process gas inflow space body 131 through the process gas supply tube 133. Thus, a tube connected to the process gas storage tank may extend along the wall of the upper chamber inner housing to define the process gas supply tube 133. Thus, the process gas may be supplied into the process gas inflow space body through the process gas supply tube 133.

Also, the upper chamber inner housing includes a process gas discharge unit 140 for discharging the process gas that is used for the substrate processing process to the outside. As illustrated in FIG. 6, the process gas discharge unit 140 includes a process gas discharge space body 141, a gas discharge hole 142, a process gas discharge tube 143, and a discharge pump (not shown). The process gas discharge space body 141 may be a space body having an inner space defined by upper/lower and left/right walls. The process gas remaining within the upper chamber inner housing 110 after being used for the substrate processing may be introduced into the process gas discharge space body 141 to exist in the process gas discharge space body 141. The gas discharge hole 142 may be provided in plurality of in a surface of the process gas discharge space body. The process remaining in the inner space of the upper chamber inner housing after being used for the substrate processing may flow into the process gas discharge space body 141 through the gas discharge hole 142. The wall of the process gas discharge space body 141, in which the gas discharge hole is defined, may be a surface facing the boat. The process gas discharge tube 143 connects the inner space of the process gas discharge space body to the discharge pump. The process gas discharge tube 143 may be connected to the inside of the process gas and then be connected to the discharge pump (not shown) along the inside of the wall of the upper chamber inner housing. Thus, the process gas within the process gas discharge space body 141 may be discharged to the outside through the process gas discharge tube 143. The discharge pump (not shown) may be pumped for discharging the process gas to the outside through the process gas discharge tube.

As described above, the process gas inflow space body 131 and the process gas discharge space body 141 each of which has the inner space are defined in the wall of the upper chamber inner housing. Here, the process gas inflow space body 131 and the process gas discharge space body 141 may be disposed at positions that face each other with the boat therebetween. The process gas injected into the process gas inflow space body 131 may pass through the gap between the substrates mounted on the boat by a pumping discharge pressure to flow into the process gas discharge space body 141, thereby being discharged to the outside. The process gas inflow space body 131 and the process gas discharge space body 141 may be buried in the sidewall of the upper chamber inner housing. Alternatively, the process gas inflow space body 131 and the process gas discharge space body 141 may be provided as separate mechanisms and then be coupled to each other in an inner surface of the sidewall.

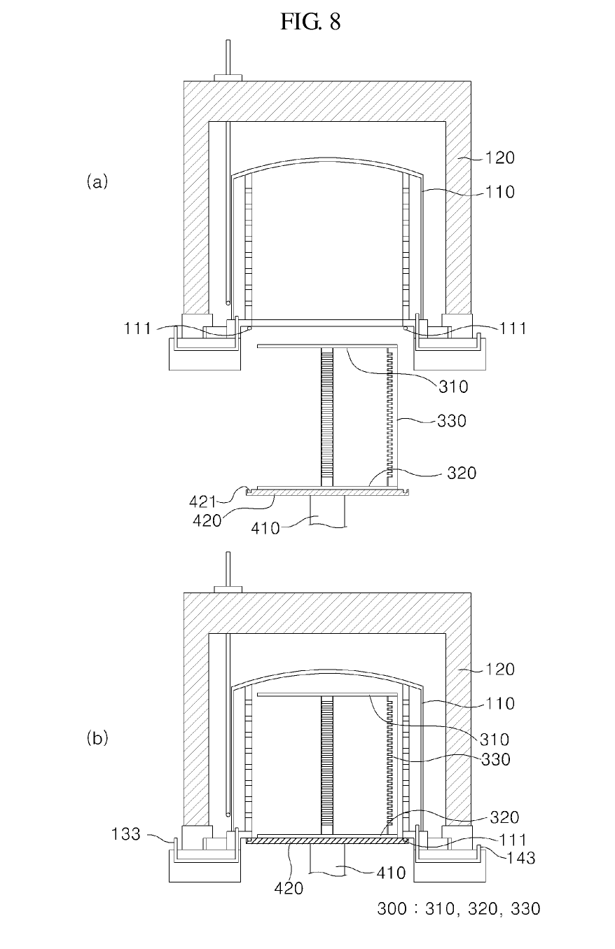

For reference, FIG. 7 is a view of the process chamber when viewed from above, i.e., illustrates the process gas that flows along the other sidewall from one sidewall of the upper chamber inner housing according to an embodiment of the present invention. The process gas injected from the gas injection hole of the process gas inflow space body 130 may horizontally pass through the inner space of the upper chamber inner housing 110 to flow into the process gas discharge space body 140 disposed on the other sidewall that faces and opposite to the one sidewall. The process gas flow may be induced by a discharge pressure of the pump connected to the process gas discharge space body 140.

When the substrate is mounted on the boat 300 to ascend into the inner space of the upper chamber inner housing 110, the boat and the upper chamber housing may be sealed to maintain sealability with respect to the outside. To maintain the sealability (airtightness), the boat support 420 and the upper chamber inner housing 120 may be sealed by a sealing element coupling body such as an O-ring. For this, as illustrated in FIG. 8A, an O-ring groove 421 is defined in a top surface of an outer circumferential portion of the boat support 420. The top surface of the outer circumferential portion may be a surface that contacts a bottom surface of the upper chamber inner housing 110. An O-ring 111 may be defined on the bottom surface of the upper chamber inner housing 110 contacting the boat support 420, which faces the O-ring groove 421 of the boat support. Thus, when the boat 300 ascends and is accommodated into the upper chamber inner housing 110, the O-ring disposed on the bottom surface of the upper chamber inner housing may be inserted into the O-ring groove defined in the top surface of the boat support as illustrated in FIG. 8B to maintain the sealability.

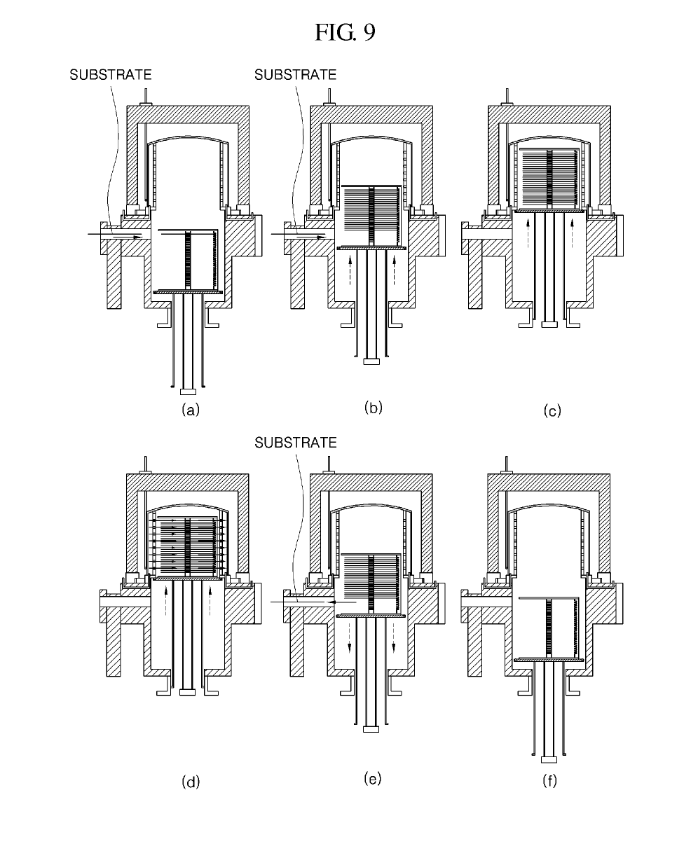

FIG. 9 is a view illustrating a process in which the substrate is loaded on the boat and is processed within a chamber housing, and then, is unloaded again from the boat according to an embodiment of the present invention.

When explaining a loading process, the substrate may be transferred to and seated into the substrate seat groove of the last stage of the boat through the substrate transfer gate as illustrated in FIG. 9A. When the substrate is seated, the boat may ascend so that the next substrate seat groove is disposed to correspond to the substrate transfer gate, and then the transferred substrate may be seated into the corresponding substrate seat groove. Thus, as illustrated in FIG. 9B, the boat ascends, and the substrate is seated into the substrate seat groove. When the substrate is seated as the boat ascends, as illustrated in FIG. 9C, the boat in which the substrate is seated into the substrate seat groove is accommodated into the upper chamber inner housing. Thereafter, as illustrated in FIG. 9D, the process gas flows out of the sidewall to contact the top surface of the substrate, thereby processing the top surface of the substrate. When the substrate processing process is completed, as illustrated in FIG. 9E, the substrate may be unloaded again from the chamber through the substrate transfer gate. When the substrate is completely unloaded, the boat is accommodated into the lower chamber housing as illustrated in FIG. 9F.

To improve substrate processing efficiency, the process gas for processing the substrate may be excited into plasma. For this, in the embodiment of the present invention, a plasma generation unit is provided. The plasma generation unit may be used for exciting the process gas into a plasma state. The plasma generation unit may be disposed within the upper chamber housing. In case of the upper chamber housing having the double structure, the plasma generation unit may be disposed between the upper chamber inner housing and the upper chamber outer housing. The plasma generation unit may be realized by using a U-shaped plasma antenna. That is, as illustrated in FIG. 6, one end 600a to which a voltage is applied and the other end 600b that is a ground connection point may be disposed on an outer surface of the upper chamber inner housing, and the one end 600a and the other end 600b may be formed as a plasma antenna that passes in a U shape between the upper chamber inner housing and the upper chamber outer housing. For reference, the U-shaped plasma antenna may be driven in a capacitively coupled plasma manner in which the process gas is excited into plasma by using a radio frequency (RF).

When the substrate is processed, a substrate heating unit for heating the substrate such as a heater may be disposed on the boat or upper chamber housing to provide heat to the substrate.

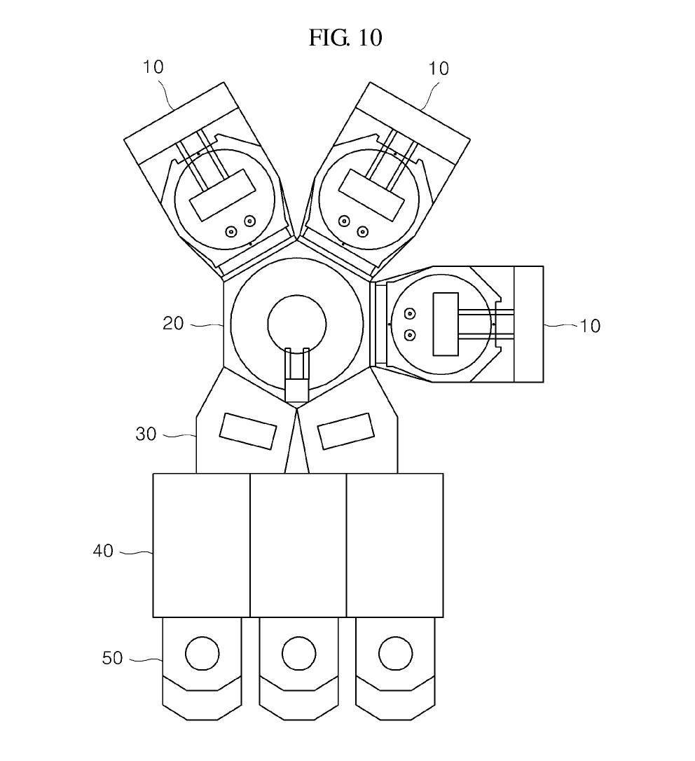

FIG. 10 is a conceptual view of the substrate processing device according to an embodiment of the present invention.

A load lock chamber 30 may generate environments that are close to environment conditions within the process chamber 10 and prevent the environment conditions within the process chamber from being affected from the outside before substrates are transferred into process chambers 10 in which the substrate processing process is performed. The load lock chamber 30 may receive a substrate from a load part 40 connected to a front opening unified pod 50 (FOUP).

The load lock chamber 30 has one surface connected to the load part 40 and the other surface connected to a transfer chamber 20 through a load lock gate. Thus, the substrates W may be disposed within the load lock chamber 30 before and after the process is performed. After the substrate is transferred from the FOUP 50 through the load part 40 in an atmospheric state, the inside of the load lock chamber 30 may change into a vacuum state like the process chamber 10. Also, when the substrate that is processed in the process chamber 10 is transferred into the load lock chamber 30 via the transfer chamber 20, the inside of the load lock chamber 30 may change into the atmospheric state, and then, the substrate may be transferred into the external FOUP 50.

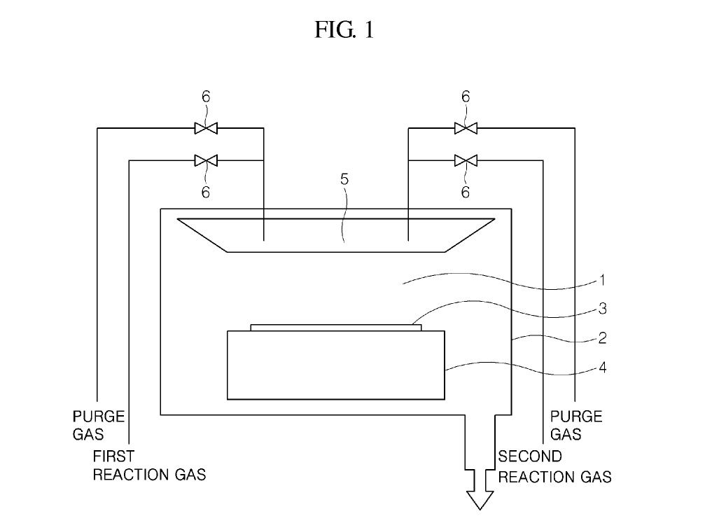

The transfer chamber 20 may be a member connecting the load lock chamber 30 to the process chamber 10. Here, the substrate W may be transferred in a vacuum state. The transfer chamber 20 may transfer the substrate transferred from the load lock chamber 30 into the process chamber 10 so as to perform the substrate processing. Also, when the substrate is completely processed, the substrate transferred from the process chamber 10 may be transferred into the load lock chamber 30. The process chamber 10 includes the boat in which a plurality of substrate are stacked to be spaced apart from each other. The process chamber 10 may rotate and simultaneously inject a process gas between the substrates that are stacked to be spaced apart from each other to discharge the process gas to the outside. As illustrated in FIGS. 1 to 6, the process chamber includes a boat 300 in which a plurality of substrates are stacked to be spaced apart from each other, a lower chamber housing 200 having a first inner space that is opened upward, an upper chamber housing 100 having a second inner space that is opened downward, the upper chamber housing 100 injecting a process gas between the substrates that are stacked to be spaced apart from each other within the boat from one side inner wall thereof to discharge the process gas to the outside toward the other side inner wall, a boat elevation unit 400 elevating the boat upward and downward between the first inner space of the lower chamber housing 200 and the second inner space of the upper chamber housing 100, and a substrate transfer gate 500 passing through one sidewall of the lower chamber housing 200. Each of the boat and the upper chamber housing may have the same structure as that of the above-described boat and upper chamber housing, and thus their detailed descriptions will be omitted.

The process chamber and the substrate processing device according to an embodiment of the present invention may be applied to device for processing various processes such as such as the chemical vapor deposition (CVD) and the atomic layer deposition (ALD). Also, according to an embodiment of the present invention, the process chamber for injecting a gas from the sidewall thereof to discharge the gas through the other side may be used to manufacture semiconductors such as LED devices and memory devices. However, the present invention is not limited thereto. For example, the process chamber may be applied to manufacture flat panel substrates such as LCDs and SOLARs.

Also, in the process chamber according to the foregoing embodiment of the present invention, the lower chamber housing may function as the substrate loading chamber, and the upper chamber housing may function as the process chamber for injecting the process gas. However, the present invention is not limited thereto. For example, it is obvious that the prevent invention may also be applied to a structure in which the lower chamber housing functions as the process chamber for injecting the process gas, and the upper chamber housing functions as the substrate loading chamber.

Although the present invention has been described with reference to the accompanying drawings and foregoing embodiments, the present invention is not limited thereto and also is limited to the appended claims. Thus, it is obvious to those skilled in the art that the various changes and modifications can be made in the technical spirit of the present invention.

1. A process chamber comprising:
a boat in which a plurality of substrates are stacked to be spaced apart from each other;
a chamber housing configured to lift the boat, thereby allowing the boat to be disposed in an inner space thereof, the chamber housing being configured to horizontally inject a process gas from a sidewall thereof, thereby allowing the process gas to flow between the substrates stacked to be apart from each other and discharge the process gas to the outside;
a boat elevation unit configured to elevate the boat into the chamber housing; and
a substrate transfer gate passing through one sidewall of the chamber housing.

2. The process chamber of claim 1, wherein the chamber housing comprises:
a lower chamber housing having a first inner space that is an inner space thereof;
an upper chamber housing disposed above the lower chamber housing and having a second inner space that is an inner space thereof, the upper chamber housing being configured to horizontally inject the process gas from a sidewall thereof, thereby allowing the process gas to flow between the substrates stacked to be spaced apart from each other and discharge the process gas to the outside.

3. The process chamber of claim 2, wherein the substrate transfer gate passes through one sidewall of the lower chamber housing.

4. The process chamber of claim 2, wherein the boat comprises:
an upper plate;
a lower plate;
a plurality of support bars connecting the upper plate to the lower plate; and
a plurality of substrate seat grooves defined in sidewalls of the support bars.

5. The process chamber of claim 4, wherein the boat elevation unit is configured to elevate the boat between the first inner space of the lower chamber housing and the second inner space of the upper chamber housing.

6. The process chamber of claim 5, wherein the boat elevation unit is configured to lift the boat for each stage so that another substrate is seated into the next substrate seat groove when a substrate is seated into the substrate seat groove through the substrate transfer gate.

7. The process chamber of claim 4, wherein the boat elevation unit comprises:
a boat support configured to support the lower plate; and
an elevation rotation driving shaft passing through a bottom surface of the lower chamber housing to elevation the boat support upward and downward.

8. The process chamber of claim 7, wherein the elevation rotation driving shaft is configured to rotate the boat support.

9. The process chamber of claim 2, wherein the upper chamber housing comprises:
an upper chamber inner housing in which the boat ascending through an opened lower side thereof is accommodated;
an upper chamber outer housing surrounding a top surface and sidewall of the upper chamber inner housing in a state where the upper chamber outer housing is spaced apart from the upper chamber inner housing;
a process gas injection unit configured to inject the process gas from one side inner wall of the upper chamber inner housing; and
a process gas discharge unit configured to discharge the process gas that is used for processing the substrate in the inner space of the upper chamber inner housing to the outside.

10. The process chamber of claim 9, wherein the process gas injection unit comprises:
a process gas inflow space body having an inner space;
a plurality of gas injection holes defined in a wall of the process gas inflow space body that is in contact with the boat; and
a process gas supply tube configured to introduce the process gas into the inner space of the process gas inflow space body.

11. The process chamber of claim 10, wherein the process gas discharge unit comprises:
a process gas discharge space body having an inner space;
a plurality of gas discharge holes defined in a wall of the process gas discharge space body that is in contact with the boat;
a discharge pump configured to pump the process gas within the inner space of the process gas discharge space body to the outside; and
a process gas discharge tube connecting the inner space of the process gas discharge space body to the discharge pump.

12. The process chamber of claim 11, wherein the process gas inflow space body and the process gas discharge space body are disposed on a wall of the upper chamber inner housing.

13. The process chamber of claim 11, wherein the process gas inflow space body and the process gas discharge space body are disposed positions that face each other.

14. The process chamber of claim 2, further comprising a plasma generation unit configured to apply a plasma voltage to the upper chamber housing.

15. The process chamber of claim 14, wherein the plasma generation unit is disposed between the upper chamber inner housing and the upper chamber outer housing.

16. The process chamber of claim 15, wherein the plasma generation unit is realized by using a U-shaped plasma antenna.

17. The process chamber of claim 16, wherein the plasma antenna has one end to which the voltage is applied and the other end that is a ground connection point, which are disposed above the upper chamber housing, and
a connection line of the one end and the other end crosses in a U shape between the upper chamber inner housing and the upper chamber outer housing.

18. A substrate processing device comprising:
a process chamber comprising a boat in which a plurality of substrates are stacked to be apart from each other, the process chamber being configured to be rotated and to inject a process gas between the substrates stacked to be spaced apart from each other, thereby discharging the process gas to the outside;
a load lock chamber that is changed from a vacuum state to an atmospheric state or from an atmospheric state to a vacuum state; and
a transfer chamber configured to transfer the substrate transferred in the load lock chamber to the process chamber, the transfer chamber being configured to transfer the substrate transferred from the process chamber to the load lock chamber.

19. The substrate processing device of claim 18, wherein the process chamber comprises:
a boat in which the plurality of substrates are stacked to be spaced apart from each other;
a lower chamber housing having a first inner space in a state where the lower chamber housing is opened upward;
an upper chamber housing having a second inner space in a state where the upper chamber housing is opened downward, the upper chamber housing being configured to inject the process gas between the substrates, which are stacked to be spaced apart from each other within the boat, from one side inner wall thereof to discharge the process gas to the outside through the other side inner wall thereof;
a boat elevation unit configured to elevate the boat between a first inner space of the lower chamber housing and a second inner space of the upper chamber housing; and
a substrate transfer gate passing through one sidewall of the lower chamber housing.

20. The substrate processing device of claim 19, wherein
the boat comprises:
an upper plate;
a lower plate;
a plurality of support bars connecting the upper plate to the lower plate; and
a plurality of substrate seat grooves defined in sidewalls of the support bars.

21. The substrate processing device of claim 19, wherein the upper chamber housing comprises:
an upper chamber inner housing in which the boat ascending through an opened lower side thereof is accommodated;
an upper chamber outer housing surrounding a top surface and sidewall of the upper chamber inner housing in a state where the upper chamber outer housing is spaced apart from the upper chamber inner housing;
a process gas injection unit configured to allow the process gas to flow from one side inner wall to the other side inner wall of the upper chamber inner housing; and
a process gas discharge unit configured to discharge the process gas that reaches the other side inner wall of the upper chamber inner housing to the outside.

22. The substrate processing device of claim 21, wherein
the process gas injection unit comprises:
a process gas inflow space body having an inner space;
a plurality of gas injection holes defined in a wall of the process gas inflow space body that is in contact with the boat; and
a process gas supply tube configured to introduce the process gas into the inner space of the process gas inflow space body.

23. The substrate processing device of claim 21, wherein the process gas discharge unit comprises:
a process gas discharge space body having an inner space;
a plurality of gas discharge holes defined in a wall of the process gas discharge space body that is in contact with the boat;
a discharge pump configured to pump the process gas within the inner space of the process gas discharge space body to the outside; and
a process gas discharge tube connecting the inner space of the process gas discharge space body to the discharge pump.

24. The substrate processing device of claim 21, wherein a plasma generation unit for applying a plasma voltage is disposed between the upper chamber inner housing and the upper chamber outer housing.

25. The substrate processing device of claim 24, wherein the plasma generation unit is realized by using a U-shaped plasma antenna.

26. The substrate processing device of claim 25, wherein the plasma antenna has one end to which the voltage is applied and the other end that is a ground connection point, which are disposed above the upper chamber housing, and
a connection line of the one end and the other end crosses in a U shape between the upper chamber inner housing and the upper chamber outer housing.
